(19) United States
(12) Patent Application Publication
(10) Pub. No.: US 2013/0128445 A1
(43) Pub. Date: May 23, 2013

(54) ELECTRONIC PRODUCT WITH VIDEO DISPLAY AND METHOD FOR ASSEMBLING THE SAME

(71) Applicant: Ching-Hung CHENG, Hsin-Chu (TW)

(72) Inventor: Ching-Hung CHENG, Hsin-Chu (TW)

(73) Assignee: AU OPTRONICS CORP., Hsin-Chu (TW)

(21) Appl. No.: 13/649,191

(22) Filed: Oct. 11, 2012

(30) Foreign Application Priority Data
Nov. 23, 2011 (TW) 100142949

(51) Int. Cl. G06F 1/16; H01R 43/00; H05K 13/04

(52) U.S. Cl. 361/679.26; 29/428; 29/825

(57) ABSTRACT

An electronic product with a video display comprises a protection sheet, a display device and a shell, wherein the display device comprises a display panel and a driver unit. The display panel has a peripheral circuit area and a display surface attached to the protection sheet. The driver unit is fixed on the protection sheet and electrically connected to the peripheral circuit area. The shell which has a bottom surface and an opening opposite to the bottom surface is used to contain the display device and the protection sheet, wherein the protection sheet covers the opening, and the display device is disposed between the protection sheet and the bottom surface of the shell.

### FIELD OF THE INVENTION

The present invention relates to an electronic product and the method for assembling the same, and more particularly to an electronic product with a video display and the method for assembling the same.

### BACKGROUND OF THE INVENTION

Along with the progress in optical technology and the process for fabricating semiconductor devices, for a consumer electronic product (such as a panel computer, a cell phone, a digital camera, a notebook and a smart phone), having a display with high definition format and characteristics of low volume and lightweight has became requisite.

To take a notebook as an example. FIG. 1 illustrates a cross-sectional view of a notebook 10 in accordance with the prior art. Generally, the notebook 10 comprises an operation system 101 and a key board 102 which are disposed in a bottom case 11 and a display panel 100 embedded in a top cover 12, wherein the bottom case 11 and the top cover 12 are engaged with a pivot structure 13.

In order to satisfy the aforementioned requirements for the consumer electronic product, some mounting kits (not shown) actually used to secure the display panel 100 mounted on the top cover 12 may be omitted. Instead, a transparent protection sheet 103 (i.e. a transparent tempered glass) is bonded on a display surface 100a of the display panel 100; and the protection sheet 103 is then directly fixed on an opening 12b of the top cover 12, thereby the display panel 100 can be disposed between a bottom surface 12a of the top cover 12 and the protection sheet 103. As a result, the assembly thickness of the top cover 12 may be reduced.

In this case, prior the protection sheet 103 is fixed on the opening 12b of the top cover 12, connecting cables or conductive wires 101a and 104a respectively connected to peripheral devices or system, such as the operation system 101 and a backlight module 104, shall be respectively engaged onto sockets 107a and 107b which are both disposed on a printed circuit board (PCB) 107.

However, since the printed circuit board 107 is connected to and fastened on a peripheral circuit area 100b of the display panel 100 merely by a unsecured flexible printed circuit (FPC) 105, thus it is difficult to engage the conductive wires 101a and 104a onto the sockets 107a and 107b, and the conductive wires 101a and 104a may vulnerable by stretching and folding due to the engagement of the conductive wires 101a and 104a and the sockets 107a and 107b.

In some other cases, for security purpose, the printed circuit board 107 may be further fixed on to a bracket 108 which protrudes from an inner surface of the top over 12 after the conductive wires 101a and 104a are engaged onto the sockets 107a and 107b. However, the bracket 108 may be too narrow to have enough strength to support the printed circuit board 107, thus the easily bended bracket 108 may cause the printed circuit board 107 swaying between the FPC 105 and the conductive wires 101a and 104a, and the conductive wires 101a and 104a may still vulnerable to stretching and folding due to the engagement of the conductive wires 101a and 104a and the sockets 107a and 107b.

Therefore, there is a need of providing an advanced electronic product with a video display and the method for assembling the same to obviate the drawbacks and problems encountered from the prior art.

### SUMMARY OF THE INVENTION

Therefore, one aspect of the present invention is to provide an advanced electronic product with a video display, so as to increase its yield.

Another aspect of the present invention is to provide an advanced method for assembling an electronic product with a video display, so as to increase its yield.

To achieve one of the aforementioned objects and other advantages of the present invention, an advanced electronic product with a video display is provided. The electronic product comprises a protection sheet, a display device and a shell, wherein the display device comprises a display panel and a driver unit. The display panel has a peripheral circuit area and a display surface attached to the protection sheet. The driver unit is fixed on the protection sheet and electrically connected to the peripheral circuit area. The shell which has a bottom surface and an opening opposite to the bottom surface is used to contain the display device and the protection sheet, wherein the protection sheet covers the opening and the display device is disposed between the protection sheet and the bottom surface of the shell.

In one embodiment of the present invention, the driver unit comprises a printed circuit board and a driving element. The printed circuit board is fixed on the protection sheet and has a carrying surface facing to the bottom surface of the shell. The driving element is fixed on the carrying surface.

In one embodiment of the present invention, the display device further comprises a backlight module disposed on the bottom surface of the shell. In this case, the display panel is disposed between the protection sheet and the backlight module.

In one embodiment of the present invention, the printed circuit board comprises a socket disposed on the carrying surface. The backlight module comprises a light emitting unit and a connecting element, wherein the connecting element connects the light emitting unit with the socket, in order to make the light emitting unit electrically connected to the driver unit. In one embodiment of the present invention, the driver unit further comprises a FPC used to connect the printed circuit board with the peripheral circuit area.

In one embodiment of the present invention, the printed circuit board is attached to the protection sheet by an adhesive layer. In one embodiment of the present invention, the electronic product further comprises a buffer layer disposed between the printed circuit board and the protection sheet, wherein the buffer layer has the adhesive layer used to attach the printed circuit board onto the protection sheet.

In one embodiment of the present invention, the printed circuit board has a socket disposed on the carrying surface. In one embodiment of the present invention, the electronic product further comprises a mainframe, wherein the mainframe has a base pivoted on the shell, an operation system disposed in the base and a connecting element used to connect the operation system with the socket in order to make the operation system electrically connected to the driver unit.

In one embodiment of the present invention, the electronic product further comprises a light-shielding layer disposed on the edge of the protection sheet used to cover a non-display area of the display panel.

To achieve one of the aforementioned objects and other advantages of the present invention, a method for assembling an electronic product with a video display is provided in order to assemble a display device into a shell. Wherein the display device comprises a display panel and a driver unit; the display panel has a display surface and a peripheral circuit area; and the driver unit is electrically connected to the peripheral circuit area of the display panel. The method for assembling the electronic product with a video display comprises steps as follows:

Firstly, the display panel and the driver unit are both fixed on a protection sheet, wherein the display surface of the display panel is attached on the protection sheet. Subsequently, the protection sheet carrying the display panel and the driver unit is disposed into the shell which has a bottom surface and an opening opposite thereto, whereby the protection sheet covers the opening, and the display is disposed between the bottom surface and the protection sheet.

In one embodiment of the present invention, prior the protection sheet carrying the display panel and the driver unit is disposed into the shell, the protection sheet is firstly held by a tool, so as to allow a socket of the driver unit being electrically connected to an extra connecting element outside of the display panel.

In one embodiment of the present invention, prior the protection sheet carrying the display panel and the driver unit is disposed into the shell, further comprises steps of disposing a backlight module into the shell.

In one embodiment of the present invention, the backlight module comprises a light emitting unit and a connecting element connected to the light emitting unit; and prior the protection sheet carrying the display panel and the driver unit is disposed into the shell, the protection sheet is firstly held by a tool, and the connecting element of the backlight module is then connected to the socket of the driver unit.

In one embodiment of the present invention, the driver unit comprises a printed circuit board and a driving element disposed on a carrying surface of the printed circuit board; and the step of fixing the driver unit on the protection sheet comprises fixing the printed circuit board on to the protection sheet in order to make the carrying surface facing the bottom surface of the shell.

In accordance with aforementioned embodiments, an electronic product with a video display and the method for assembling the same are provided. Wherein a transparent protection sheet attached with a display panel is adopted to substitute the mounting kits traditionally used to secure the display panel on a top cover. In addition, by this approach, a driver unit of the display panel can be directly fixed on the protection sheet, such that a bracket traditionally used to secure the driver unit can be also omitted. Thus while the electronic product is thinner, the problems of insufficient strength in the bracket and the vulnerability of conductive wires to the assembling process can be solved, and the yield of the electronic product may be significantly increased.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 illustrates a cross-sectional view of a notebook in accordance with the prior art;

FIG. 2 illustrates a cross-sectional view of a notebook in accordance with one embodiment of the present invention; and

FIGS. 3A through 3B are cross-sectional views illustrating partial steps for assembling the notebook depicted on FIG. 2.

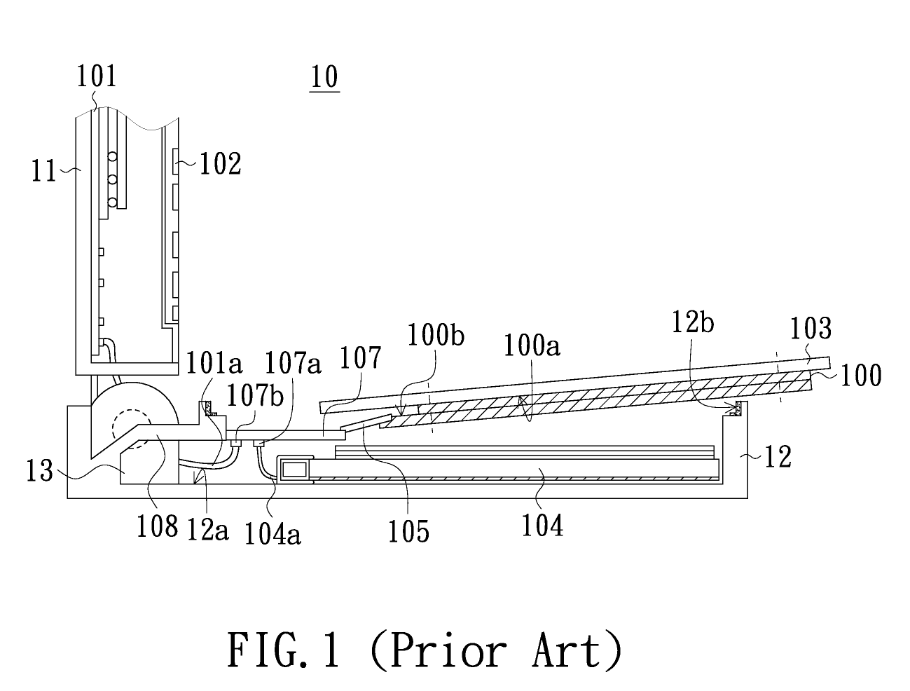

### DETAILED DESCRIPTION OF PREFERRED EMBODIMENTS

The present invention is to provide an electronic product with a video display and the method for assembling the same in order to solve the problems of a bracket with insufficient strength and conductive wires vulnerable to the assembling process, whereby the yield of the electronic product can be increased. The present invention will now be described more specifically by taking a notebook as a preferred embodiment. It is to be noted that the following descriptions of the preferred embodiment are presented herein for purpose of illustration and description only. It is not intended to be exhaustive or to be limited to the precise form disclosed.

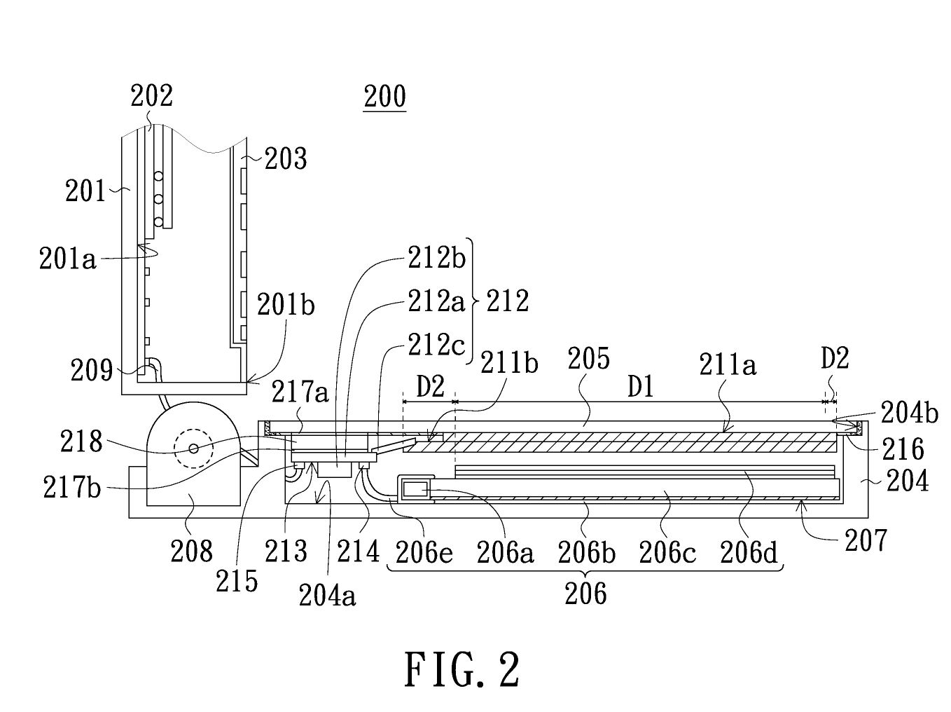

FIG. 2 illustrates a cross-sectional view of a notebook 200 in accordance with one embodiment of the present invention. The notebook 200 comprises a base 201, an operation system 202, a key board 203, a shell 204, a protection sheet 205 and a display device 207.

Wherein the base 201 is another shell structure engaged with the shell 204 by a pivot structure 208 and has a bottom surface 201a and an opening 201b opposite to the bottom surface 201a. The operation system which is used to control and computing the notebook 200 is disposed on the bottom surface 201a within the base 201 and electrically connected to the display device 207 by a connecting element 209, wherein the connecting element 209, for example, can be a low-voltage differential signaling (LVDS) line. The keyboard 203 is disposed on the opening 201b of the base 201.

In the present embodiment, the display device 207 comprises a display panel 211, a driver unit 212 and a backlight module 206, wherein the display panel 211 is a non-self-luminous panel, such as a liquid crystal display (LCD) panel. However, in some other embodiments, the display panel 211 may be a self-luminous panel and, in these cases, the backlight module 206 may be omitted. The display panel 211 has a display surface 211a and a peripheral circuit area 211b, wherein the display surface 211a is attached to the protection sheet 205, and the peripheral circuit area 211b is electrically connected to the driver unit 212. In some embodiments of the present invention, the display surface 211a is directly adhered onto the protection sheet 205 by surface mounting technology, wherein the display panel 211 can be divided into a display area D1 and a non-display area D2 (as defined by the dotted lines).

The shell 204 has a bottom surface 204a and an opening 204b opposite to the bottom surface 204a. The backlight module 206 is disposed on the bottom surface 204a of the shell 204. In some embodiments of the present invention, the backlight module 206 comprises a light emitting unit 206a, a reflect sheet 206b, a light guide plate 206c, optical films 206d and a connecting element 206e, wherein the connecting element 206e is electrically connected to the driver unit 212. In the present embodiment, the connecting element 206e is a conductive wire electrically connecting the backlight module 206 with the driver unit 212.

The protection sheet 205 is a cover lens consisting of transparent material (such as tempered glass or plastic) which covers on the opening 204b of the shell 204. The display device 207 is disposed between the backlight module 206 and the protection sheet 206. In the present embodiment, a light shielding layer 216 is attached onto the edge of the protection sheet 204 in order to cover the non-display area D2 of the display panel 211.

The driver unit 212 is fixed on the protection sheet 205. In some embodiments of the present invention, the driver unit 212 comprises a printed circuit board 212a, a driving element 212b and a FPC 212c, wherein the printed circuit board 212a has a carrying surface 213 facing to the bottom surface 204a of the shell 204 and allowing the driving element 212b disposed thereon; and the surface of the printed circuit board 212a opposite to the carrying surface 213 is attached on one side of the protection sheet 204 facing to the bottom surface 204a of the shell 204.

In the present embodiment, the printed circuit board 212a is adhered on the protection sheet 205 by a buffer layer 218 which has two adhesive layers 217a and 217b on its opposite sides. In addition, the buffer layer 218 can absorb the compression subject to the protection sheet 205 and the printed circuit board 212a. In some other embodiments, the printed circuit board 212a, however, is adhered on the protection sheet 205 merely by a single adhesive layer.

The printed circuit board 212a further comprises a plurality of sockets, such as the sockets 214 and 215 which are electrically connected to the backlight module 206 and the operation system 202 respectively. In the present embodiment, the sockets 214 and 215 of the printed circuit board 212a are respectively engaged with the connecting element 206e which is eclectically connected to the backlight module 206 and the connecting element 209 which is eclectically connected to the operation system 202. Meanwhile, the peripheral circuit area 211b of the display panel 211 is electrically connected to the printed circuit board 212a by the FPC 212c.

Because the printed circuit board 212a can be securely fixed on the protection sheet 205, thus the printed circuit board 212a unlikely sways around. As a result, compression, stretching and folding may not subject to the connecting elements 206e and 209 during the steps for respectively engaging the connecting elements 206e and 209 with the sockets 214 and 215; and the FPC 212c used to electrically connect the printed circuit board 212a and the peripheral circuit area 211b may hardly be broken or peeled off from the printed circuit board 212a. Furthermore, since the traditional bracket used to fix the printed circuit board 212a is not necessary any more, in the present embodiment, thus the structure of the shell 204 can be simplified, and the steps for assembling the protection sheet 205 and the display device 207 onto the shell 204 can be performed more easily, without the bracket lies in the way.

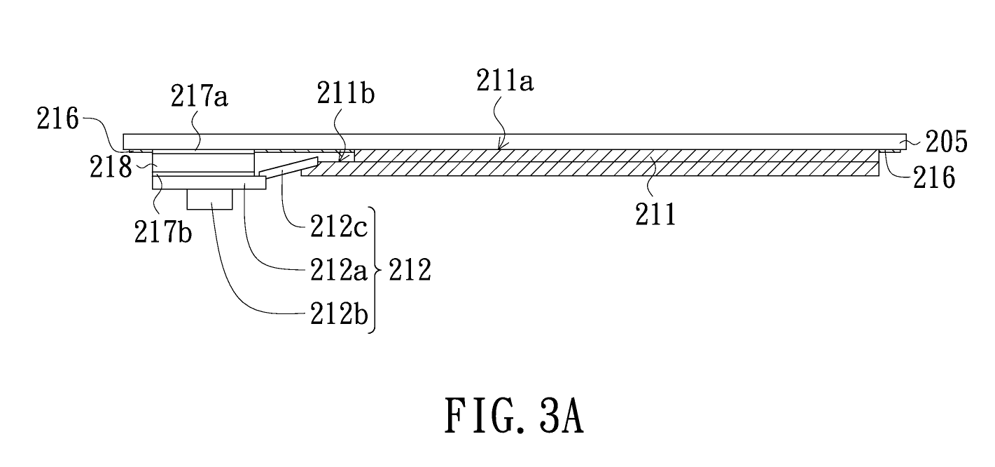

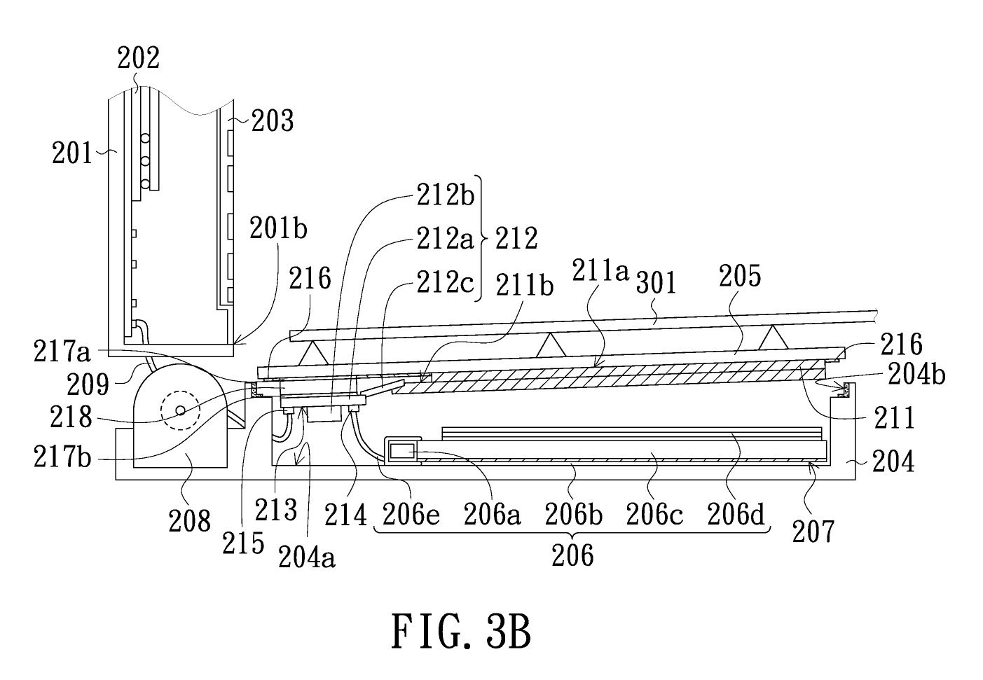

FIGS. 3A through 3B are cross-sectional views illustrating partial steps for assembling the notebook 200 depicted on FIG. 2. Wherein the method for assembling the notebook 200 comprises steps as follows:

A display device 207 having a display panel 211 and a driver unit 212 are firstly provided. The display panel 211 and the driver unit 212 are then fixed onto a protection sheet 205, whereby a display surface 211a of the display panel 211 is attached on the protection sheet 205. In the present embodiment, the driver unit 212 comprises a printed circuit board 212a and a driving element 212b, wherein the driving element 212b is disposed on a carrying surface 213 of the printed circuit board 212a, the printed circuit board 212a is adhered on the protection sheet 205 by a buffer layer 218 with two adhesive layers 217a and 217b on its opposite sides (see FIG. 3A), and the carrying surface 213 of the printed circuit board 212a may be held to face a bottom surface 204a of a shell 204 at subsequent steps.

Next, a backlight module 206 is disposed on the bottom surface 204a of the shell 204. At some other embodiments, the backlight module 206 assembling step may be omitted, however, if the display panel 211 is a self-luminous panel. The protection sheet 205 which carries the display panel 211 and the driver unit 212 is then held by a tool 301. Subsequently, sockets 214 and 215 which disposed on the printed circuit board 212a are respectively engaged with a connecting element 206e which is eclectically connected to the backlight module 206 and a connecting element 209 which is eclectically connected to an operation system 202 of the notebook 200 (see FIG. 3B).

The tool 301 is then driven to dispose the protection sheet 205 which carries the display panel 211 and the driver unit 212 into the shell 204, whereby the protection sheet 205 can cover an opening 204b of the shell 204, and the display device 207 can be disposed between the bottom surface 204a and the protection sheet 205, as shown in FIG. 2B. Subsequent steps (not shown) may be then performed to finish the assembly of the notebooks 200 depicted in FIG. 2.

In accordance with aforementioned embodiments, an electronic product with a video display and the method for assembling the same are provided. Wherein a transparent protection sheet attached with a display panel is firstly adopted to substitute the mounting kits traditionally used to secure the display panel on a shell. Subsequently, a driver unit used to drive the display panel is directly fixed onto the protection sheet. By this approach, the bracket traditionally used to support the driver unit is not necessary any more.

Since the driver unit is directly attached on the protection sheet, thus the driver unit can be fixed more securely and the bracket can be omitted, so as to simplify the structure of the shell. In addition, without the bracket lies in the way, the process may be carried out more easily for assembling the display device into the shell. Thus while the electronic product is thinned out, the problems of insufficient strength in the bracket and the vulnerability of conductive wires to the assembling process can be solved, and the yield of the electronic product may be significantly increased.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An electronic product with a video display, comprising:
a protection sheet;
a display device, comprising:
a display panel, having a peripheral circuit area and a display surface attached on the protection sheet; and
a driver unit, fixed to the protection sheet and electrically connected to the peripheral circuit area; and
a shell, containing the display device and the protection sheet, wherein the shell has a bottom surface and a an opening opposite to the bottom surface, the protection sheet covers the opening, and the display device is disposed between the protection sheet and the bottom surface.

2. The electronic product according to claim 1, wherein the driver unit comprises:
a printed circuit board, fixed to the protection sheet and having a carrying surface facing to the bottom surface; and
a driving element, fixed on the carrying surface.

3. The electronic product according to claim 2, wherein the display device further comprises a backlight module disposed on the bottom surface of the shell, and the display panel is disposed between the protection sheet and the backlight module.

4. The electronic product according to claim 3, wherein the printed circuit board comprises a first socket disposed on the carrying surface, the backlight module comprises a light emitting unit and a connecting element connecting the light emitting unit with the socket, in order to make the light emitting unit electrically connected to the driver unit.

5. The electronic product according to claim 2, wherein the driver unit further comprises a flexible printed circuit connecting the printed circuit board with the peripheral area.

6. The electronic product according to claim 2, further comprising an adhesive layer used to attach the printed circuit board onto the protection sheet.

7. The electronic product according to claim 6, further comprising a buffer layer disposed between the printed circuit board and the protection sheet, wherein the buffer layer has the adhesive layer used to attach the printed circuit board to the protection sheet.

8. The electronic product according to claim 2, wherein the printed circuit board has a second socket disposed on the carrying surface.

9. The electronic product according to claim 8, further comprising a mainframe, wherein the mainframe comprises:
a base pivotally connected to the shell;
an operation system disposed in the base; and
a connecting element connecting the operation system with the socket in order to make the operation system electrically connected to the driver unit.

10. The electronic product according to claim 8, further comprising a light-shielding layer disposed on the edge of the protection sheet used to cover a non-display area of the display panel.

11. A method for assembling an electronic product with a video display used to assemble a display device into a shell, wherein the display device comprises a display panel and a driver unit; the display panel has a display surface and a peripheral circuit area; and the driver unit is electrically connected to the peripheral circuit area of the display panel, the method comprising:
fixing the display panel and the driver unit on a protection sheet, wherein the display surface of the display panel is attached on the protection sheet; and
disposing the protection sheet carrying the display panel and the driver unit into the shell which has a bottom surface and an opening opposite to the bottom surface, whereby the display panel covers the opening, and the display panel is disposed between the bottom surface and the protection sheet.

12. The method according to claim 11, further comprising:
holding the protection sheet by a tool; and
electrically connecting a socket of the driver unit to a connecting element outside of the display panel, prior the protection sheet carrying the display panel and the driver unit is disposed into the shell.

13. The method according to claim 11, wherein the display device further comprises a backlight module, and the method further comprises a step of disposing the backlight module into the shell, prior the protection sheet carrying the display panel and the driver unit is disposed into the shell.

14. The method according to claim 13, wherein the backlight module comprises a light emitting unit and a connecting element connected to the light emitting unit; and prior the protection sheet carrying the display panel and the driver unit is disposed into the shell, the method further comprises steps of:
holding the protection sheet by a tool; and
electrically connecting the connecting element of the backlight module to the socket of the driver unit.

15. The method according to claim 11, wherein the driver unit comprises a printed circuit board and a driving element disposed on a carrying surface of the printed circuit board; and the step of fixing the driver unit on the protection sheet comprises fixing the printed circuit board on the protection sheet in order to make the carrying surface facing the bottom surface of the shell.
